(19) United States
(12) Patent Application Publication
(10) Pub. No.: US 2021/0009859 A1
(43) Pub. Date: Jan. 14, 2021

(54) CHEMICAL MECHANICAL POLISHING SLURRY COMPOSITION FOR POLISHING MULTIPLE FILMS AND POLISHING METHOD USING THE SAME

(71) Applicant: KCTECH CO., LTD., Gyeonggi-do (KR)

(72) Inventors: Ji Hye KIM, Gyeonggi-do (KR); Bo Hyeok CHOI, Gyeonggi-do (KR); Jae Woo LEE, Gyeonggi-do (KR); Jae Ik LEE, Gyeonggi-do (KR)

(73) Assignee: KCTECH CO., LTD., Gyeonggi-do (KR)

(21) Appl. No.: 16/918,139

(22) Filed: Jul. 1, 2020

(30) Foreign Application Priority Data
Jul. 10, 2019 (KR) 10-2019-0083159

(51) Int. Cl. C09G 1/02; C09K 3/14

(52) U.S. Cl. CPC C09G 1/02; C09K 3/1409

(57) ABSTRACT

A chemical mechanical polishing (CMP) slurry composition for polishing multiple films and a polishing method using the CMP slurry composition are provided. The CMP slurry composition includes abrasive particles, a surface roughness modifier including a water-soluble polymer, a polishing regulator including an organic acid, and a polishing profile improving agent including a nonionic surfactant.

### CROSS-REFERENCE TO RELATED APPLICATION(S)

This application claims the benefit of Korean Patent Application No. 10-2019-0083159, filed on Jul. 10, 2019, in the Korean Intellectual Property Office, the disclosure of which is incorporated herein by reference.

### BACKGROUND

### 1. Field of the Invention

One or more example embodiments relate to a chemical mechanical polishing (CMP) slurry composition for polishing multiple films and a polishing method using the CMP slurry composition.

### 2. Description of the Related Art

In a semiconductor process, chemical mechanical polishing or planarization (CMP) is used as a surface polishing process to form a multi-layered device with a high integration density, and an importance of a polishing process for fabricating a pattern is gradually increasing as a pattern size of a semiconductor gradually decreases.

In a process of fabricating a semiconductor device, a monocrystalline silicon wafer that is capable of making initial materials at a low cost and making an oxide film with excellent electrical insulation properties, is used as a main material. Since surface roughness of a silicon wafer in a semiconductor process has a great influence on subsequent processes, a planarization process using CMP is essential.

Polycrystalline silicon thin films are currently used in processes for fabricating an integrated circuit (IC), a recess channel array transistor (RCAT), and a three-dimensional (3D) fin field-effect transistor (FinFET), and there is a need for research on minimization of surface roughness using CMP.

Specifically, polycrystalline silicon is obtained by crystallizing amorphous silicon. A widely used laser crystallization method has a disadvantage in that surface roughness of a polycrystalline silicon film is poor, and thus there is an essential need to improve the surface roughness.

CMP slurry compositions are used to polish silicon materials, for example, a simple substance of silicon such as monocrystalline silicon, amorphous silicon or polysilicon, and silicon compounds such as silicon nitride or silicon oxide. For example, CMP slurry compositions are being used to polish a silicon substrate such as a monocrystalline silicon substrate, or to polish a film of a simple substance of silicon such as an amorphous silicon film or a polysilicon film formed on a silicon substrate, or a film of a silicon compound such as a silicon nitride film or a silicon oxide film.

Generally, there are various types of CMP slurry compositions depending on characteristics and types of polishing targets. However, recently, development of CMP slurry compositions capable of simultaneously polishing a silicon film, a silicon nitride film and a silicon oxide film is required.

In this regard, research and development of CMP slurry compositions for enhancing a polishing selectivity and a polishing speed have been actively conducted. However, there are few studies on a multi-functional slurry composition capable of simultaneously improving surface roughness and occurrences of defects or scratches when CMP slurry compositions are applied to different types of films.

### SUMMARY

The present disclosure is to solve the foregoing problems, and an aspect of the present disclosure is to provide a chemical mechanical polishing (CMP) slurry composition for polishing multiple films which may improve surface roughness of a polycrystalline silicon film while improving defects of the polycrystalline silicon film and a silicon nitride film, and provide a polishing method using the CMP slurry composition.

However, the problems to be solved in the present disclosure are not limited to the aforementioned problems, and other problems to be solved, which are not mentioned above, will be clearly understood by a person having ordinary skill in the art from the following description.

According to an aspect, there is provided a CMP slurry composition for polishing multiple films, the CMP slurry composition including abrasive particles, a surface roughness modifier including a water-soluble polymer, a polishing regulator including an organic acid, and a polishing profile improving agent including a nonionic surfactant.

The CMP slurry composition may further include a defect improving agent including an anionic surfactant.

The anionic surfactant may include at least one of polyacrylic acid, polymethacrylic acid, a polystyrene-acrylic acid copolymer, an acrylic acid-maleic acid copolymer, an acrylic acid-ethylene copolymer, an acrylic acid-acrylamide copolymer, and an acrylic acid-poly acrylamide copolymer.

The defect improving agent may be present in an amount of 0.005% by weight (wt %) to 0.1 wt % in the CMP slurry composition.

The abrasive particles may include at least one of a metal oxide, a metal oxide coated with an organic material or inorganic material, and a metal oxide in a colloidal phase. The metal oxide may include at least one of silica, ceria, zirconia, alumina, titania, barium titania, germania, mangania, and magnesia.

The abrasive particles may be prepared by a liquid-phase method, and may be dispersed so that a surface of the abrasive particles may have negative charges.

The abrasive particles may have a particle size of 10 nanometers (nm) to 200 nm. The abrasive particles may be present in an amount of 0.1 wt % to 10 wt % in the CMP slurry composition.

The water-soluble polymer may have a weight average molecular weight of 10,000 to 1,000,000.

The water-soluble polymer may include at least one of hydroxyethyl cellulose (HEC), hydroxymethyl cellulose (HMC), hydroxypropyl cellulose (HPC), hydroxypropyl methylcellulose (HPMC), carboxymethyl cellulose (CMC), methylcellulose (MC), methyl hydroxyethyl Cellulose (MHEC), chitosan, gelatin, xanthan gum, collagen, carrageenan, flurane, pectin, chondroitin sulfate, alginic acid, dextran, beta-glucan, and hyaluronic acid.

The surface roughness modifier may be present in an amount of 0.0005 wt % to 0.5 wt % in the CMP slurry composition.

The organic acid may include at least one of succinic acid, malic acid, malonic acid, adipic acid, tartaric acid, glutaric acid, glycollic acid, aspartic acid, itaconic acid, tricarballylic acid, pimelic acid, suberic acid, sebacic acid, stearic acid, pyruvic acid, acetoacetic acid, glyoxylic acid, azelaic acid, fumaric acid, glutaconic acid, traumatic acid, muconic acid, aconic acid, carballylic acid, tribasic acid, mellitic acid, isocitric acid, citric acid, lactic acid, gluconic acid, maleic acid, ascorbic acid, iminoacetic acid, oxalic acid, pyrogallic acid, formic acid, acetic acid, propionic acid, butyric acid, valeric acid, hexanoic acid, heptanoic acid, caprylic acid, nonanoic acid, decanoic acid, undecylic acid, lauric acid, tridecylic acid, myristic acid, pentadecanoic acid, and palmitic acid.

The polishing regulator may be present in an amount of 0.01 wt % to 1 wt % in the CMP slurry composition.

The CMP slurry composition may further include a pH adjuster. The pH adjuster may include at least one of triethanolamine, trimethanolamine, monoethanolamine, diethanolamine, dimethylbenzylamine, ethoxybenzylamine, 2-amino-2-methyl-1-propanol, 2-amino-2-ethyl-1,3-propanediol, tris(hydroxymethyl)aminomethane, 2-amino-1-butanol, 2-amino-2-methyl-1,3-propanediol, dimethylamino methylpropanol, diethylaminoethanol, monoisopropanolamine, aminoethylethanolamine, 3-amino-1-propanol, 2-amino-1-propanol, 1-amino-2-propanol, 1-amino-pentanol, 2-(2-aminoethylamino)ethanol, 2-dimethylamino-2-methyl-1-propanol, and N,N-diethylethanolamine.

The nonionic surfactant may include at least one of polyethylene glycol (PEG), polypropylene glycol (PPG), a polyethylene-propylene copolymer, polyalkyl oxide, polyoxyethylene (POE), polyethylene oxide (PEO), and polypropylene oxide.

The polishing profile improving agent may be present in an amount of 0.01 wt % to 1 wt % in the CMP slurry composition.

The CMP slurry composition may have pH of 3 to 7.

The multiple films may include either a polycrystalline silicon film or a silicon nitride film, or both.

Additional aspects of example embodiments will be set forth in part in the description which follows and, in part, will be apparent from the description, or may be learned by practice of the disclosure.

According to example embodiments, a CMP slurry composition for polishing multiple films may include a surface roughness modifier including a water-soluble polymer, to improve surface roughness after polishing the multiple films that include either a polycrystalline silicon film or a silicon nitride film or both.

Also, the CMP slurry composition may include a defect improving agent including an anionic surfactant, to improve an occurrence of a defect after polishing the multiple films that include either a polycrystalline silicon film or a silicon nitride film or both.

### DETAILED DESCRIPTION

Hereinafter, example embodiments will be described in detail. However, various alterations and modifications may be made to the example embodiments. Here, the example embodiments are not construed as limited to the disclosure and should be understood to include all changes, equivalents, and replacements within the idea and the technical scope of the disclosure.

The terminology used herein is for the purpose of describing particular example embodiments only and is not to be limiting of the example embodiments. As used herein, the singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In addition, in the description of example embodiments, detailed description of well-known related structures or functions will be omitted when it is deemed that such description will cause ambiguous interpretation of the present disclosure.

Hereinafter, a chemical mechanical polishing (CMP) slurry composition for polishing multiple films and a polishing method using the CMP slurry composition will be described in detail with reference to example embodiments. However, the present disclosure is not limited to the example embodiments.

According to an aspect, a CMP slurry composition for polishing multiple films is provided. The CMP slurry composition may include abrasive particles, a surface roughness modifier including a water-soluble polymer, a polishing regulator including an organic acid, and a polishing profile improving agent including a nonionic surfactant.

The CMP slurry composition may include the surface roughness modifier including a water-soluble polymer, and thus it is possible to increase a rate of removal of a surface hillock occurring when polycrystalline silicon is grown, and to improve surface roughness after polishing of a film to be polished.

The CMP slurry composition may further include a defect improving agent including an anionic surfactant.

The anionic surfactant may include at least one of polyacrylic acid, polymethacrylic acid, a polystyrene-acrylic acid copolymer, an acrylic acid-maleic acid copolymer, an acrylic acid-ethylene copolymer, an acrylic acid-acrylamide copolymer, and an acrylic acid-poly acrylamide copolymer.

The anionic surfactant may have a weight average molecular weight of 1,000 to 30,000. The weight average molecular weight of the anionic surfactant may desirably range from 1,000 to 25,000, more desirably range from 1,500 to 25,000, and even more desirably 1,500 to 20,000.

When the weight average molecular weight of the anionic surfactant is less than 1,000, a defect improvement rate may decrease. When the weight average molecular weight of the anionic surfactant exceeds 30,000, the polishing speed may decrease.

The defect improving agent may be present in an amount of 0.005 wt % to 0.1 wt % in the CMP slurry composition.

When the amount of the defect improving agent is less than 0.01 wt %, the defect improvement rate may decrease. When the amount of the defect improving agent exceeds 0.1 wt %, an aggregation phenomenon may occur or a dispersion stability may decrease, and the defect improvement rate may decrease.

The abrasive particles may include at least one of a metal oxide, a metal oxide coated with an organic material or inorganic material, and a metal oxide in a colloidal phase. The metal oxide may include at least one of silica, ceria, zirconia, alumina, titania, barium titania, germania, mangania, and magnesia.

A surface of the abrasive particles may be modified from OH to COO—. Through the above surface modification, the abrasive particles may have strong negative charges in all pH ranges. Due to a strong repulsive force between the surface-modified abrasive particles and the polycrystalline silicon film, adsorption of the polycrystalline silicon film to the abrasive particles may be minimized after polishing.

The abrasive particles may be prepared by a liquid-phase method, and may be dispersed so that a surface of the abrasive particles may have negative charges.

The abrasive particles may include, but are not limited to, for example, abrasive particles prepared by a liquid-phase method. The liquid-phase method may include, for example, a sol-gel method of causing a chemical reaction of abrasive particle precursors in an aqueous solution and of growing crystals, to obtain minute particles, or a coprecipitation method of coprecipitating ions of abrasive particles in an aqueous solution, and a hydrothermal synthesis of forming abrasive particles under high-temperature and high-pressure conditions. The abrasive particles prepared by the liquid-phase method may be dispersed so that the surface of the abrasive particles may have negative charges.

The abrasive particles may have a particle size of 10 nanometers (nm) to 200 nm.

The particle size of the abrasive particles may desirably range from 10 nm to 150 nm, more desirably range from 30 nm to 150 nm, and even more desirably range from 30 nm to 100 nm.

An average particle size of the abrasive particles may be measured as an average value of particle sizes of a plurality of particles within a field of view which may be measured by a scanning electron microscope analysis or dynamic light scattering. When the particle size of the abrasive particles is less than 10 nm, a polishing rate for the particle size of the abrasive particles may decrease, and it may be difficult to achieve a desired selectivity. When the particle size of the abrasive particles exceeds 200 nm, it may be difficult to control a selectivity due to excessive polishing, and dishing, erosion and surface defects may be likely to occur.

The abrasive particles may be mixed particles with a multi-dispersion type particle distribution, in addition to a single-size particle. For example, abrasive particles with two different types of average particle sizes may be mixed to have a bimodal particle distribution, or abrasive particles with three different types of average particle sizes may be mixed to have a particle size distribution showing three peaks. Also, abrasive particles with at least four different types of average particle sizes may be mixed to have a multi-dispersion type particle distribution. Relatively large abrasive particles and relatively small abrasive particles may be mixed, to have a better dispersibility, and an effect of reducing scratches on a wafer surface may be expected.

The abrasive particles may have at least one of a spherical shape, a square shape, a needle shape, and a plate shape, and may desirably be the spherical shape.

The abrasive particles be monocrystalline. When monocrystalline abrasive particles are used, a scratch reduction effect may be achieved in comparison to polycrystalline abrasive particles, dishing may be improved, and cleanability after polishing may be enhanced.

The abrasive particles may be present in an amount of 0.1 wt % to 10 wt % in the CMP slurry composition.

When the amount of the abrasive particles is less than 1 wt %, a polishing speed may decrease. When the amount of the abrasive particles exceeds 10 wt %, the polishing speed may significantly increase, and surface defects may be caused by adsorbability of particles remaining on a surface due to an increase in a number of abrasive particles.

The water-soluble polymer may have a weight average molecular weight of 10,000 to 1,000,000.

When the weight average molecular weight of the water-soluble polymer is less than 10,000, a hillock on the polycrystalline silicon film may not be easily removed. When the weight average molecular weight of the water-soluble polymer exceeds 1,000,000, the hillock may be excessively removed and a film to be polished may be lost.

To remove the hillock on the polycrystalline silicon film, forming a laminar flow between a pad and a polycrystalline silicon wafer by a slurry composition during polishing is important. When the slurry composition is in a turbulent flow state due to a failure of formation of the laminar flow between the pad and the polycrystalline silicon wafer, mechanical polishing may be irregularly performed so that a surface may be rough. To form a laminar flow, a water-soluble polymer with a relatively long molecular chain may desirably be added.

The water-soluble polymer may include at least one of hydroxyethyl cellulose (HEC), hydroxymethyl cellulose (HMC), hydroxypropyl cellulose (HPC), hydroxypropyl methylcellulose (HPMC), carboxymethyl cellulose (CMC), methylcellulose (MC), methyl hydroxyethyl Cellulose (MHEC), chitosan, gelatin, xanthan gum, collagen, carrageenan, flurane, pectin, chondroitin sulfate, alginic acid, dextran, beta-glucan, and hyaluronic acid.

Among the above-described water-soluble polymers, water-soluble polymer cellulose may be cellulose obtained from photosynthesis of plants and may be prepared and used by hydrolyzing lignocellulosic cellulose regardless of a presence or absence of lignin, or water-soluble polymer cellulose industrially prepared and sold may be used.

The surface roughness modifier may be present in an amount of 0.0005 wt % to 0.5 wt % in the CMP slurry composition.

When the amount of the surface roughness modifier is less than 0.0005 wt %, a hillock on a polycrystalline silicon film may not be easily removed. When the amount of the surface roughness modifier exceeds 0.5 wt %, the hillock may be excessively removed during polishing of the polycrystalline silicon film, and a film to be polished may be lost.

The organic acid may include at least one of succinic acid, malic acid, malonic acid, adipic acid, tartaric acid, glutaric acid, glycollic acid, aspartic acid, itaconic acid, tricarballylic acid, pimelic acid, suberic acid, sebacic acid, stearic acid, pyruvic acid, acetoacetic acid, glyoxylic acid, azelaic acid, fumaric acid, glutaconic acid, traumatic acid, muconic acid, aconic acid, carballylic acid, tribasic acid, mellitic acid, isocitric acid, citric acid, lactic acid, gluconic acid, maleic acid, ascorbic acid, iminoacetic acid, oxalic acid, pyrogallic acid, formic acid, acetic acid, propionic acid, butyric acid, valeric acid, hexanoic acid, heptanoic acid, caprylic acid, nonanoic acid, decanoic acid, undecylic acid, lauric acid, tridecylic acid, myristic acid, pentadecanoic acid, and palmitic acid.

The polishing regulator may be present in an amount of 0.01 wt % to 1 wt % in the CMP slurry composition.

When the amount of the polishing regulator is less than 0.01 wt %, the polishing speed may decrease. When the amount of the polishing regulator exceeds 1 wt %, a film to be polished may be excessively polished.

The CMP slurry composition may further include a pH adjuster. The pH adjuster may include at least one of triethanolamine, trimethanolamine, monoethanolamine, diethanolamine, dimethylbenzylamine, ethoxybenzylamine, 2-amino-2-methyl-1-propanol, 2-amino-2-ethyl-1,3-propanediol, tris(hydroxymethyl)aminomethane, 2-amino-1-butanol, 2-amino-2-methyl-1,3-propanediol, dimethylamino methylpropanol, diethylaminoethanol, monoisopropanolamine, aminoethylethanolamine, 3-amino-1-propanol, 2-amino-1-propanol, 1-amino-2-propanol, 1-amino-pentanol, 2-(2-aminoethylamino)ethanol, 2-dimethylamino-2-methyl-1-propanol, and N,N-diethylethanolamine.

The pH adjuster may be present in an amount of 0.01 wt % to 1 wt % in the CMP slurry composition.

When the amount of the pH adjuster is less than 0.01 wt %, the polishing speed may decrease. When the amount of the pH adjuster exceeds 1 wt %, a film to be polished may be excessively polished.

The nonionic surfactant may include at least one of polyethylene glycol (PEG), polypropylene glycol (PPG), a polyethylene-propylene copolymer, polyalkyl oxide, polyoxyethylene (POE), polyethylene oxide (PEO), and polypropylene oxide.

The nonionic surfactant may have a weight average molecular weight of 100 to 1,000.

The polishing profile improving agent may be present in an amount of 0.01 wt % to 1 wt % in the CMP slurry composition.

When the amount of the polishing profile improving agent is less than 0.01 wt %, excessive polishing may occur. When the amount of the polishing profile improving agent exceeds 1 wt %, micro-scratches may occur due to a decrease in a dispersion stability of a composition.

The CMP slurry composition may have pH of 3 to 7.

When the pH is less than 3 or exceeds 7, the defect improvement rate may decrease.

The multiple films may include either a polycrystalline silicon film or a silicon nitride film, or both.

According to another aspect, there is provided a polishing method including polishing a semiconductor wafer including multiple films using the above-described CMP slurry composition for polishing the multiple films.

Hereinafter, the present disclosure will be described in detail with reference to examples and comparative examples. However, the technical idea of the present disclosure is not limited or restricted thereto.

### Example 11

1 wt % of surface-modified colloidal silica abrasive particles (PL-3D) with a particle size of 80 nm, 0.08 wt % of succinic acid as carboxylic acid, 0.03 wt % of hydroxyethyl cellulose (HEC) with a weight average molecular weight of 90,000 as a surface roughness modifier, 0.05 wt % of polyethylene glycol (PEG) with a weight average molecular weight of 600 as a polishing profile improving agent, and 0.025 wt % of polyacrylic acid (PAA 1λ) with a weight average molecular weight of 2,000 as a defect improving agent were added, and triethanolamine as a pH adjuster was mixed, to prepare a CMP slurry composition for polishing multiple films that have pH of 3.5.

Polishing was performed using the CMP slurry composition for 60 seconds under evaluation conditions of a pressure of 2 psi, a carrier RPM of 78/83 and a flow rate of 250 ml/min.

### Example 2

A CMP slurry composition for polishing multiple films was prepared in the same manner as in Example 1, except that 0.005 wt % of polyacrylic acid (PAA 1×) as a defect improving agent was added.

Polishing was performed using the prepared CMP slurry composition under the same evaluation conditions as those of Example 1.

### Example 3

A CMP slurry composition for polishing multiple films was prepared in the same manner as in Example 1, except that 0.005 wt % of polyacrylic acid (PAA 1×) with a weight average molecular weight of 10,000 as a defect improving agent was added.

Polishing was performed using the prepared CMP slurry composition under the same evaluation conditions as those of Example 1.

### Example 4

A CMP slurry composition for polishing multiple films was prepared in the same manner as in Example 1, except that pH was adjusted to 4.5.

Polishing was performed using the prepared CMP slurry composition under the same evaluation conditions as those of Example 1.

### Example 5

A CMP slurry composition for polishing multiple films was prepared in the same manner as in Example 1, except that pH was adjusted to 4.5 and that 0.005 wt % of polyacrylic acid (PAA 1×) as a defect improving agent was added.

Polishing was performed using the prepared CMP slurry composition under the same evaluation conditions as those of Example 1.

### Example 6

A CMP slurry composition for polishing multiple films was prepared in the same manner as in Example 1, except that pH was adjusted to 4.5 and that 0.005 wt % of polyacrylic acid (PAA 1×) with a weight average molecular weight of 10,000 as a defect improving agent was added.

Polishing was performed using the prepared CMP slurry composition under the same evaluation conditions as those of Example 1.

### Example 7

A CMP slurry composition for polishing multiple films was prepared in the same manner as in Example 1, except that pH was adjusted to 4.5 and that 0.0025 wt % of polyacrylic acid (PAA 5×) with a weight average molecular weight of 10,000 as a defect improving agent was added.

Polishing was performed using the prepared CMP slurry composition under the same evaluation conditions as those of Example 1.

### Comparative Example 1

A CMP slurry composition for polishing multiple films was prepared in the same manner as in Example 1, except that polyacrylic acid (PAA 1×) as a defect improving agent was not added.

Polishing was performed using the prepared CMP slurry composition under the same evaluation conditions as those of Example 1.

### Comparative Example 2

A CMP slurry composition for polishing multiple films was prepared in the same manner as in Comparative Example 1, except that pH was adjusted to 4.5.

Polishing was performed using the prepared CMP slurry composition under the same evaluation conditions as those of Example 1.

### Comparative Example 3

A CMP slurry composition for polishing multiple films was prepared in the same manner as in Example 1, except that pH was adjusted to 2.5.

Polishing was performed using the prepared CMP slurry composition under the same evaluation conditions as those of Example 1.

### Comparative Example 4

A CMP slurry composition for polishing multiple films was prepared in the same manner as in Example 1, except that 0.15 wt % of polyacrylic acid (PAA 1×) was added.

Polishing was performed using the prepared CMP slurry composition under the same evaluation conditions as those of Example 1.

### Comparative Example 5

A CMP slurry composition for polishing multiple films was prepared in the same manner as in Example 1, except that 0.001 wt % of polyacrylic acid (PAA 5×) with a weight average molecular weight of 10,000 was added.

Polishing was performed using the prepared CMP slurry composition under the same evaluation conditions as those of Example 1.

### Comparative Example 6

A CMP slurry composition for polishing multiple films was prepared in the same manner as in Example 1, except that pH was adjusted to 4.5 and that 0.001 wt % of polyacrylic acid (PAA 5×) with a weight average molecular weight of 10,000 was added.

Polishing was performed using the prepared CMP slurry composition under the same evaluation conditions as those of Example 1.

### Comparative Example 7

A CMP slurry composition for polishing multiple films was prepared in the same manner as in Example 1, except that pH was adjusted to 7.5 and that 0.005 wt % of polyacrylic acid (PAA 5×) with a weight average molecular weight of 10,000 was added.

Polishing was performed using the prepared CMP slurry composition under the same evaluation conditions as those of Example 1.

### Comparative Example 8

A CMP slurry composition for polishing multiple films was prepared in the same manner as in Example 1, except that polystyrene sulfonic acid (PSSA) as a defect improving agent was added.

Polishing was performed using the prepared CMP slurry composition under the same evaluation conditions as those of Example 1.

### Comparative Example 9

A CMP slurry composition for polishing multiple films was prepared in the same manner as in Example 1, except that 2-acrylamido-2-methylpropane sulfonic acid (AMPS) as a defect improving agent was added.

Polishing was performed using the prepared CMP slurry composition under the same evaluation conditions as those of Example 1.

### Comparative Example 10

A CMP slurry composition for polishing multiple films was prepared in the same manner as in Example 1, except that ammonium lauryl sulfate (ALS) as a defect improving agent was added.

Polishing was performed using the prepared CMP slurry composition under the same evaluation conditions as those of Example 1.

### Comparative Example 11

A CMP slurry composition for polishing multiple films was prepared in the same manner as in Example 1, except that ammonium persulfate (APS) as a defect improving agent was added.

Polishing was performed using the prepared CMP slurry composition under the same evaluation conditions as those of Example 1.

Polishing was performed using the CMP slurry compositions of Examples 1 to 7 and Comparative Examples 1 to 11 under the following polishing conditions:

[Polishing Conditions]

1. Polishing machine: NT (manufactured by KCTECH)

2. Pad: IC 1000 (manufactured by DOW)

3. Carrier RPM (Carrier RPM): 78/83

4. Wafer pressure: 2 psi

5. Flow rate: 250 ml/min

6. Polishing time: 60 sec

Measurement results for defect occurrence rates based on conditions of pH, wt % and types of polyacrylic acid included in the CMP slurry compositions of Examples 1 to 7 and Comparative Examples 1 to 7 are shown in Table 1 below.

The defect occurrence rates were calculated as Post/Pre by measuring the total number (Pre) of defects of the wafer before evaluation and the total number (Post) of defects of the wafer after CMP in a DSA mode using SP2XP of KLA-Tencor.

TABLE 1

| | | Defect improving agent | | Defect |
|---|---|---|---|---|
| | pH | Type | wt % | Post/Pre(%) |
| Example 1 | 3.5 | PAA 1X | 0.025 | 3.504 |
| Example 2 | 3.5 | PAA 1X | 0.005 | 7.472 |
| Example 3 | 3.5 | PAA 5X | 0.005 | 6.988 |
| Example 4 | 4.5 | PAA 1X | 0.025 | 7.156 |
| Example 5 | 4.5 | PAA 1X | 0.005 | 9.864 |
| Example 6 | 4.5 | PAA 5X | 0.005 | 7.806 |
| Example 7 | 4.5 | PAA 5X | 0.0025 | 13.945 |
| Comparative | 3.5 | — | — | 36.68 |
| Example 1 | | | | |
| Comparative | 4.5 | — | — | 59.32 |
| Example 2 | | | | |
| Comparative | 2.5 | PAA 1X | 0.025 | 37.685 |
| Example 3 | | | | |
| Comparative | 3.5 | PAA 1X | 0.15 | 18.347 |
| Example 4 | | | | |
| Comparative | 3.5 | PAA 5X | 0.001 | 19.674 |
| Example 5 | | | | |
| Comparative | 4.5 | PAA 5X | 0.001 | 25.648 |
| Example 6 | | | | |
| Comparative | 7.5 | PAA 5X | 0.005 | 37.891 |
| Example 7 | | | | |

Referring to Table 1, it may be confirmed that in the CMP slurry compositions of Examples 1 to 7 including the defect improving agents, the defect occurrence rates are significantly reduced in comparison to defect occurrence rates for the CMP slurry compositions of Comparative Examples 1 and 2 that do not include defect improving agents. Also, comparison of results of Comparative Examples 3 and 7 and results of Examples 1 and 3 shows that the defect occurrent rate increases when the pH decreases to pH 2.5 or when the pH increases to pH 7.5 under the same conditions.

Comparison of the result of Example 1 and the result of Comparative Example 4 shows that the defect occurrence rate increases when the amount of polyacrylic acid that is a defect improving agent increases under the same conditions. Also, comparison of results of Examples 3 and 6 and results of Comparative Examples 5 and 6 shows that the defect occurrence rate increases when the amount of polyacrylic acid decreases under the same conditions.

Measurement results for defect occurrence rates based on conditions of pH, wt % and types of defect improving agents included in the CMP slurry compositions of Example 1 and Comparative Examples 8 to 11 are shown in Table 2 below.

The defect occurrence rates were calculated as Post/Pre by measuring the total number (Pre) of defects of the wafer before evaluation and the total number (Post) of defects of the wafer after CMP in the DSA mode using SP2XP of KLA-Tencor.

TABLE 2

| | | Defect improving agent | | Defect |
|---|---|---|---|---|
| | pH | Type | wt % | Post/Pre(%) |
| Example 1 | 3.5 | PAA 1X | 0.025 | 3.504 |
| Comparative | 3.5 | PSSA | 0.025 | 28.170 |
| Example 8 | | | | |
| Comparative | 3.5 | AMPS | 0.05 | 26.204 |
| Example 9 | | | | |
| Comparative | 3.5 | ALS | 0.025 | 27.169 |
| Example 10 | | | | |
| Comparative | 3.5 | APS | 0.025 | 22.697 |
| Example 11 | | | | |

Referring to Table 2, it may be confirmed that a defect occurrence rate of 20% or greater is measured when another anionic surfactant, instead of the polyacrylic acid, is included as a defect improving agent.

While a few example embodiments have been shown and described, it will be apparent to those skilled in the art that various modifications and variations can be made from the foregoing descriptions. For example, adequate effects may be achieved even if the foregoing processes and methods are carried out in different order than described above, and/or the aforementioned elements, such as systems, structures, devices, or circuits are combined or coupled in different forms and modes than as described above or be substituted or switched with other components or equivalents.

Thus, other implementations, alternative embodiments and equivalents to the claimed subject matter are construed as being within the appended claims.

What is claimed is:

1. A chemical mechanical polishing (CMP) slurry composition for polishing multiple films, the CMP slurry composition comprising:
abrasive particles;
a surface roughness modifier comprising a water-soluble polymer;
a polishing regulator comprising an organic acid; and
a polishing profile improving agent comprising a nonionic surfactant;

2. The CMP slurry composition of claim 1, further comprising a defect improving agent comprising an anionic surfactant.

3. The CMP slurry composition of claim 2, wherein the anionic surfactant comprises at least one selected from the group consisting of polyacrylic acid, polymethacrylic acid, a polystyrene-acrylic acid copolymer, an acrylic acid-maleic acid copolymer, an acrylic acid-ethylene copolymer, an acrylic acid-acrylamide copolymer, and an acrylic acid-poly acrylamide copolymer.

4. The CMP slurry composition of claim 2, wherein the defect improving agent is present in an amount of 0.005% by weight (wt %) to 0.1 wt % in the CMP slurry composition.

5. The CMP slurry composition of claim 1, wherein
the abrasive particles comprise at least one selected from the group consisting of a metal oxide, a metal oxide coated with an organic material or inorganic material, and a metal oxide in a colloidal phase, and
the metal oxide comprises at least one selected from the group consisting of silica, ceria, zirconia, alumina, titania, barium titania, germania, mangania, and magnesia.

6. The CMP slurry composition of claim 1, wherein the abrasive particles are prepared by a liquid-phase method, and are dispersed so that a surface of the abrasive particles has negative charges.

7. The CMP slurry composition of claim 1, wherein the abrasive particles have a particle size of 10 nanometers (nm) to 200 nm.

8. The CMP slurry composition of claim 1, wherein the abrasive particles are present in an amount of 0.1 wt % to 10 wt % in the CMP slurry composition.

9. The CMP slurry composition of claim 1, wherein the water-soluble polymer has a weight average molecular weight of 10,000 to 1,000,000.

10. The CMP slurry composition of claim 1, wherein the water-soluble polymer comprises at least one selected from the group consisting of hydroxyethyl cellulose (HEC), hydroxymethyl cellulose (HMC), hydroxypropyl cellulose (HPC), hydroxypropyl methylcellulose (HPMC), carboxymethyl cellulose (CMC), methylcellulose (MC), methyl hydroxyethyl Cellulose (MHEC), chitosan, gelatin, xanthan gum, collagen, carrageenan, flurane, pectin, chondroitin sulfate, alginic acid, dextran, beta-glucan, and hyaluronic acid.

11. The CMP slurry composition of claim 1, wherein the surface roughness modifier is present in an amount of 0.0005 wt % to 0.5 wt % in the CMP slurry composition.

12. The CMP slurry composition of claim 1, wherein the organic acid comprises at least one selected from the group consisting of succinic acid, malic acid, malonic acid, adipic acid, tartaric acid, glutaric acid, glycollic acid, aspartic acid, itaconic acid, tricarballylic acid, pimelic acid, suberic acid, sebacic acid, stearic acid, pyruvic acid, acetoacetic acid, glyoxylic acid, azelaic acid, fumaric acid, glutaconic acid, traumatic acid, muconic acid, aconic acid, carballylic acid, tribasic acid, mellitic acid, isocitric acid, citric acid, lactic acid, gluconic acid, maleic acid, ascorbic acid, iminoacetic acid, oxalic acid, pyrogallic acid, formic acid, acetic acid, propionic acid, butyric acid, valeric acid, hexanoic acid, heptanoic acid, caprylic acid, nonanoic acid, decanoic acid, undecylic acid, lauric acid, tridecylic acid, myristic acid, pentadecanoic acid, and palmitic acid.

13. The CMP slurry composition of claim 1, wherein the polishing regulator is present in an amount of 0.01 wt % to 1 wt % in the CMP slurry composition.

14. The CMP slurry composition of claim 1, further comprising:
a pH adjuster,
wherein the pH adjuster comprises at least one selected from the group consisting of triethanolamine, trimethanolamine, monoethanolamine, diethanolamine, dimethylbenzylamine, ethoxybenzylamine, 2-amino-2-methyl-1-propanol, 2-amino-2-ethyl-1,3-propanediol, tris(hydroxymethyl)aminomethane, 2-amino-1-butanol, 2-amino-2-methyl-1,3-propanediol, dimethylamino methylpropanol, diethylaminoethanol, monoisopropanolamine, aminoethylethanolamine, 3-amino-1-propanol, 2-amino-1-propanol, 1-amino-2-propanol, 1-amino-pentanol, 2-(2-aminoethylamino)ethanol, 2-dimethylamino-2-methyl-1-propanol, and N,N-diethylethanolamine.

15. The CMP slurry composition of claim 1, wherein the nonionic surfactant comprises at least one selected from the group consisting of polyethylene glycol (PEG), polypropylene glycol (PPG), a polyethylene-propylene copolymer, polyalkyl oxide, polyoxyethylene (POE), polyethylene oxide (PEO), and polypropylene oxide.

16. The CMP slurry composition of claim 1, wherein the polishing profile improving agent is present in an amount of 0.01 wt % to 1 wt % in the CMP slurry composition.

17. The CMP slurry composition of claim 1, wherein the CMP slurry composition has pH of 3 to 7.

18. The CMP slurry composition of claim 1, wherein the multiple films comprise either a polycrystalline silicon film or a silicon nitride film, or both.
